(19) United States
(12) Patent Application Publication
(10) Pub. No.: US 2019/0145002 A1
(43) Pub. Date: May 16, 2019

(54) SHOWERHEAD AND SUBSTRATE PROCESSING DEVICE INCLUDING THE SAME

(71) Applicant: SAMSUNG ELECTRONICS CO., LTD., SUWON-SI (KR)

(72) Inventors: JUNG HWAN UM, SEONGNAM-SI (KR); DAE GYU BAN, HWASEONG-SI (KR)

(21) Appl. No.: 16/013,986

(22) Filed: Jun. 21, 2018

(30) Foreign Application Priority Data
Nov. 16, 2017 (KR) 10-2017-0153205

(51) Int. Cl. C23C 16/455; H01J 37/32; H01L 21/67

(52) U.S. Cl. CPC C23C 16/45565; C23C 16/45557; H01L 21/67069; H01J 37/32449

(57) ABSTRACT

A showerhead has a body portion includes first and second surface opposite surfaces, a gas supply channel open at the first surface, and a plurality of gas injecting holes connected to the gas supply channel and open at the second surface to allow gas delivered through the gas supply channel to be discharged from the showerhead at the second surface. The second surface has a first region and a second region, divided by a first virtual line passing through a center of the second surface. The gas injecting holes are inclined in directions substantially perpendicular to the first virtual line to discharge gas in directions away from the first virtual line, and gas injecting holes open at the first region and the second region are inclined in opposite directions.

### PRIORITY STATEMENT

This application claims benefit of priority under 35 U.S.C. § 119 to Korean Patent Application No. 10-2017-0153205 filed on Nov. 16, 2017 in the Korean Intellectual Property Office, the disclosure of which is hereby incorporated by reference in its entirety.

### BACKGROUND

### 1. Field

The present inventive concept relates to a showerhead, to a substrate processing device or apparatus including the same, and to a method of processing a substrate using gas ejected from a showerhead.

### 2. Description of Related Art

In general, semiconductor devices, such as integrated circuits (ICs), are formed on a semiconductor wafer. Such semiconductor devices may be formed by repeatedly performing semiconductor processes, such as a deposition process, a photolithography process, and an etching process, on a semiconductor wafer. In these respects, these process should be carried out uniformly over the entire area of the wafer, even in the case of manufacturing a semiconductor device having a variety of patterns especially when such patterns have a high aspect ratio.

### SUMMARY

[symbol]

According to an aspect of the present inventive concept, there is provide a showerhead comprising a body having a first surface, a second surface opposite the first surface, a gas supply channel open at the first surface, and a plurality of gas injecting holes in open communication with the gas supply channel and open at the second surface to allow gas, delivered through the gas supply channel, to be discharged from the showerhead at the second surface. The second surface has a first region and a second region on opposite sides of a first virtual line passing through a center of the second surface. In a vertical sectional view of the body in which the first surface faces up and the second surface faces down, each of the gas injecting holes is inclined, relative to a line perpendicular to the second surface, in a direction whose horizontal component is substantially parallel to the second surface and perpendicular to the first virtual line. Also, the gas injecting holes open at the first region of the second surface are inclined oppositely with respect to the gas injecting holes open at the second region in such that gas discharged from the gas injecting holes at the second surface flows away from the first virtual line when viewed in a plan view of the showerhead.

According to an aspect of the present inventive concept, there is also provided a showerhead comprising a cylindrical body including a gas discharge surface having a circular form, a gas supply channel configured to allow a source gas to flow thereinto, and a plurality of gas injecting holes connected to the gas supply channel and open at the gas discharge surface to discharge gas delivered from the gas supply channel from the showerhead at the gas discharge surface. The plurality of gas injecting holes are laid out on the gas discharge surface in concentric circles and are thus open at a first region or a second region of the discharge surface on opposite sides of a first virtual line passing through a center of the gas discharge surface. The gas injecting holes open at the first region have bilateral symmetry with respect to the gas injecting holes open at the second region. Also, the gas injecting holes open at the first region are inclined oppositely relative to the gas injecting holes open at the second region to discharge gas away from the first virtual line in directions of a second virtual line substantially perpendicular to the first virtual line as viewed in a plan view of the showerhead.

According to an aspect of the present inventive concept, there is also provided a substrate processing device comprising a processing chamber having a reaction space therein, a substrate support disposed in a lower portion of the processing chamber and dedicated to support a substrate, and a showerhead disposed in an upper portion of the processing chamber and having a gas discharge surface opposing the substrate support. The showerhead comprises a body including a gas supply channel and a plurality of gas injecting holes in open communication with the gas supply channel and open at the gas discharge surface such that source gas delivered through the gas supply channel is discharged from the showerhead at the gas discharge surface thereof into the reaction space, the gas discharge surface having a first region and a second region on opposites sides of a first virtual line passing through a center of the gas discharge surface. Each of the gas injecting holes is inclined, relative to a line perpendicular to the gas discharge surface, in a direction whose horizontal component is substantially parallel to the gas discharge surface and perpendicular to the first virtual line. Also, the gas injecting holes open at the first region of the gas discharge surface are inclined oppositely with respect the gas injecting holes open at the second region such that the source gas discharged from the gas injecting holes at the gas discharge surface flows away from the first virtual line when viewed in a plan view of the substrate processing device.

According to an aspect of the present inventive concept, there is also provided a substrate processing device comprising a processing chamber having a reaction space therein and lower part including a gas outlet, a substrate support disposed in a lower portion of the processing chamber and dedicated to support a substrate, the substrate support having a substrate support surface disposed at a level above that of the gas outlet, a showerhead disposed in an upper portion of the processing chamber and having a gas discharge surface opposing the substrate support, and an exhaust system connected to the gas outlet to draw gas out of the process chamber through the gas outlet. The showerhead comprises a body including a gas supply channel and a plurality of gas injecting holes in open communication with the gas supply channel and open at the gas discharge surface such that source gas delivered through the gas supply channel is discharged from the showerhead at the gas discharge surface thereof into the reaction space, the gas discharge surface having a first region and a second region on opposites sides of a first virtual line passing through a center of the gas discharge surface. Each of the gas injecting holes is inclined, relative to a line perpendicular to the gas discharge surface, in a direction whose horizontal component is substantially parallel to the gas discharge surface and perpendicular to the first virtual line. Furthermore, the gas injecting holes open at the first region of the gas discharge surface are inclined oppositely with respect to the gas injecting holes open at the second region such that the source gas discharged from the gas injecting holes at the gas discharge surface flows away from the first virtual line when viewed in a plan view of the substrate processing device. Also, the gas outlet to which the exhaust system is connected has a plurality of sections disposed as spaced from each other in a circumferential direction of the lower part of the processing chamber.

### BRIEF DESCRIPTION OF DRAWINGS

The above and other aspects, features, and advantages of the inventive concept will be more clearly understood from the following detailed description of examples thereof, taken in conjunction with the accompanying drawings, in which:

FIG. 1 is a schematic cross-sectional view of an example of a substrate processing device according to the inventive concept;

FIG. 2 is a plan view of the layout of gas outlets of a showerhead employed in the substrate processing device of FIG. 1;

FIG. 3 is a cross-sectional view of the showerhead taken along line of FIG. 2;

FIG. 4 is a plan view of an exhaust port of the substrate processing device of FIG. 1;

FIG. 5A is a plan view of the same type of exhaust port but schematically shows gas flow distribution in a substrate processing device according to related art;

FIG. 5B is a plan view of the same type of exhaust port but schematically shows gas flow distribution in a substrate processing device according to the inventive concept;

FIG. 6 includes a schematic perspective view of a line pattern of a semiconductor device disposed in a portion of the substrate processing device corresponding to region “A” of FIG. 5A, and a conceptual diagram of the processing of the line pattern;

FIGS. 7A and 7B are a plan view and a cross-sectional view of another example of a showerhead according to the inventive concept; and

FIG. 8 is a cross-sectional view of still another example of a showerhead according to the inventive concept.

### DETAILED DESCRIPTION

Hereinafter, examples of the present inventive concept will be described with reference to the accompanying drawings.

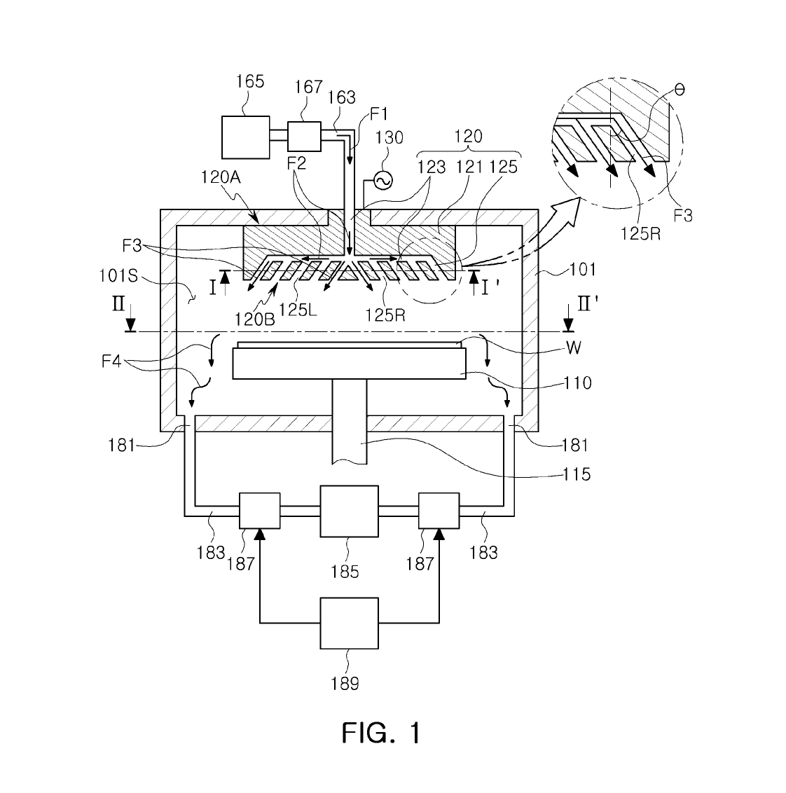

FIG. 1 is a schematic cross-sectional view of an example a substrate processing device according to the inventive concept.

With reference to FIG. 1, the substrate processing device may include a processing chamber 101 having a reaction space 101S, a substrate support 110 disposed in a lower portion of the reaction space 101S and dedicated (configured and otherwise adapted) to support a substrate W, and a showerhead 120 disposed in an upper portion of the reaction space 101S.

The substrate processing device may be provided as a capacitively coupled plasma (CCP) reaction device and may include a radio frequency (RF) power source 130 generating plasma.

The showerhead 120 may not only discharge processing gas towards the substrate W, but also play a role as an RF electrode to generate plasma. In more detail, the showerhead 120 may be connected to the RF power source 130 to generate plasma in the reaction space 101S of the processing chamber 101. To this end, the showerhead 120 may include a conductive material or a metallic electrode.

The substrate processing device may include a gas supply line 163 supplying processing gas from a gas source 165. The substrate processing device may selectively supply a desired amount of processing gas (marked “F1”) through a gas supply line 163 using a mass flow controller (MFC) and a valve 167.

The showerhead 120 may have a first surface 120A connected to the gas supply line 163 and a second surface 120B disposed to oppose the first surface 120A to serve as a gas discharge surface. The showerhead 120 may be disposed such that the second surface 120B, i.e., the gas discharge surface, may oppose the substrate W disposed on the substrate support 110.

The showerhead 120 may comprise a body portion 121 including a gas supply channel 123 connected to the gas supply line 163 at the first surface 120A and including a plurality of gas injecting holes 125 connected to the gas supply channel 123 and open at the second surface 120B. To this end, the lower end of the gas supply channel may form a plenum in the body of the showerhead 120 (shown but not numbered in FIG. 1). Processing gas having flowed out of the gas supply line 163 may be supplied to the plurality of gas injecting holes 125 through (the plenum of) the gas supply channel 123 (as marked “F2”) and may be discharged in a direction towards the substrate W from the second surface 120B through the plurality of gas injecting holes 125 (as marked “F3”). The gas injecting holes 125 may each be a passageway in the showerhead extending axially from the plenum to the discharge surface 120B at an inclination, i.e., obliquely, to a plane perpendicular to the discharge surface 120B, as will be described in more detail below.

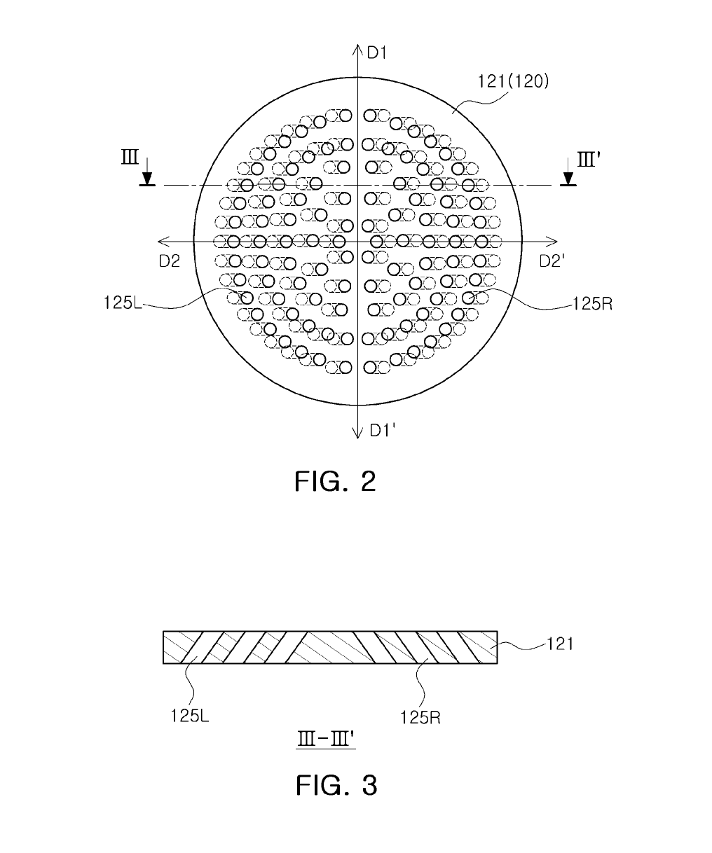

FIG. 2 is a layout diagram or plan view of gas outlets of the showerhead employed in the substrate processing device of FIG. 1 and may be similar to that at the cross section indicated by line I-I′.

With reference to FIGS. 1 and 2, a plurality of gas injecting holes 125 may open to the gas discharge surface 120B of the showerhead 120. The plurality of gas injecting holes 125 may be inclined to discharge gas in a direction away from a central portion of the gas discharge surface 120B.

In the present example, the gas injecting holes 125 are not collectively (all) inclined in respective radial directions (in directions passing through the gas injecting holes toward the outer periphery of the showerhead 120 from a central axis of the showerhead 120), and are confined to opposing sides of a virtual line D1-D1′ passing diametrically through the central axis.

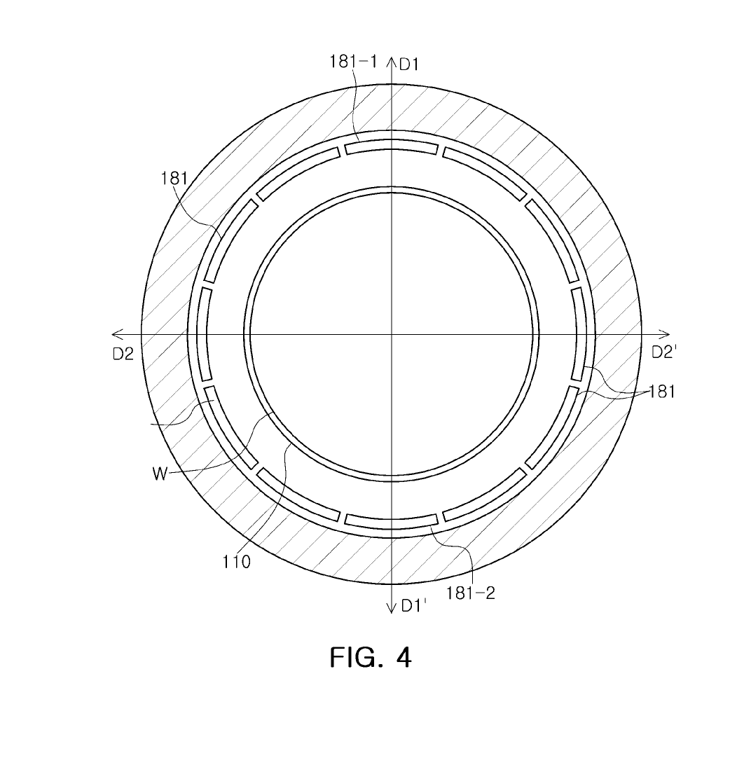

In more detail, as illustrated in FIG. 2, in a case in which the gas discharge surface 120B is divided into a first region and a second region by a first virtual line D1-D1′ passing diametrically through the center of the surface 120B, gas injecting holes 125L are confined to the first region, gas injecting holes 125R are confined to the second region and the gas injecting holes 125L are inclined in a direction (to the left in the figure parallel to second virtual line D2-D2′) opposite to a direction in which the gas injecting holes 125R are inclined (to the right in the figure parallel to second virtual line D2-D2′). For example, as illustrated in FIG. 3, in the cross-sectional view taken along line parallel to the second virtual line D2-D2′, gas injecting holes 125L and 125R may be formed to have a pattern (e.g., inclination angles) similar to those of the gas injecting holes illustrated in FIG. 1.

In addition, the gas injecting holes 125 may be arranged to have bilateral symmetry, based on a vertical plane perpendicular to the discharge surface 120B and passing through first virtual line D1-D1′. In other words, the gas injecting holes 125L of the first region may be arranged symmetrically, about the first virtual line D1-D1′, to the gas injecting holes 125R of the second region. Furthermore, a respective group of the gas injecting holes 125 is open to the discharge surface 120B at each of a plurality of concentric regions of the second surface. For example, concentric rings of the gas injecting holes 125 are provided in the case in which the gas discharge surface 120B is substantially circular. Each gas injecting hole 125 in one of the rings need not be aligned in the radial direction with one or more of the gas injecting holes 125 in the other rings.

Therefore, a main discharge direction of the processing gas, i.e., the horizontal component of the direction along which gas ejected from the inclined gas injecting holes 125L and 125R flows, may be the same axial direction as the second virtual line D2-D2′ perpendicular to the first virtual line D1-D1′. Here, the horizontal component is parallel to the surface of the substrate support 110 and hence, to an upper surface of a wafer W supported by the substrate support 100. Therefore, in the present example, processing gas will not be uniformly discharged in all radial directions (as viewed in a plan view of the device) but rather only discharged in left and right directions, that is, in axial directions whose horizontal components are parallel to the second virtual line D2-D2′ perpendicular to the first virtual line D1-D1′.

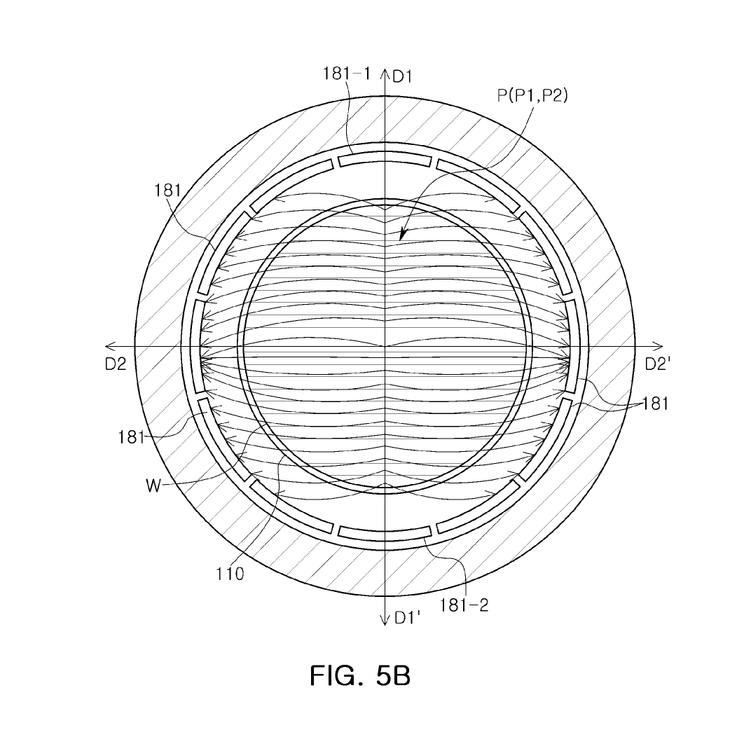

Discharge of the gas, described above, may provide a useful effect in a process of manufacturing a semiconductor device, having a specific pattern, according to the inventive concept. For example, when a line pattern is formed or a line structure is subjected to a treatment process, such as etching, the discharge of processing gas from the showerhead towards the pattern or structure may be induced in a direction whose horizontal component is parallel to the line such that overall an effective process is performed. This effect and benefit of the inventive concept will be described in more detail subsequently with reference to FIGS. 5A and 5B.

An inclination angle (θ) (of each) of the gas injecting holes 125L and 125R may be within a range of 30° to 40° to ensure that the gas flows in a desired direction. In this case, the inclination angle (θ) may be defined as an angle with respect to a virtual line perpendicular to the gas discharge surface 120B, as illustrated in the enlarged region in FIG. 1.

In an example, the gas injecting holes 125L of the first region and the gas injecting holes 125R of the second region are inclined in opposite directions, while inclination angles of the injecting holes are substantially equal. For example, an inclination angle (θ) of the gas injecting holes 125R of the second region may be about 40°, while an inclination angle (θ) of the gas injecting holes 125L of the first region may be about −40°.

A substrate processing device according to the inventive concept may include a plurality of gas outlets 181 open to the process space 101S of the processing chamber 101 in a region of the device lower than the level of the surface of the substrate support 110 on which a substrate W is disposed. The gas outlets 181 may be connected to a vacuum pump 185 through a gas exhaust line 183. Processing gas may be exhausted by vacuum suction force generated by the vacuum pump 185 when a valve(s) 187 associated with the gas outlet 181 is operated (opened) to place the gas outlet 181 in open communication with an inlet of the vacuum pump 185. While a substrate is processed, the vacuum pump 185, associated with the gas outlet 181, may be operated using a controller 189 and the controller 189 may control the operation of the valve 187 in such a way that gas (marked “F4”) is discharged from the chamber 101 after the reaction (processing of the substrate) has taken place.

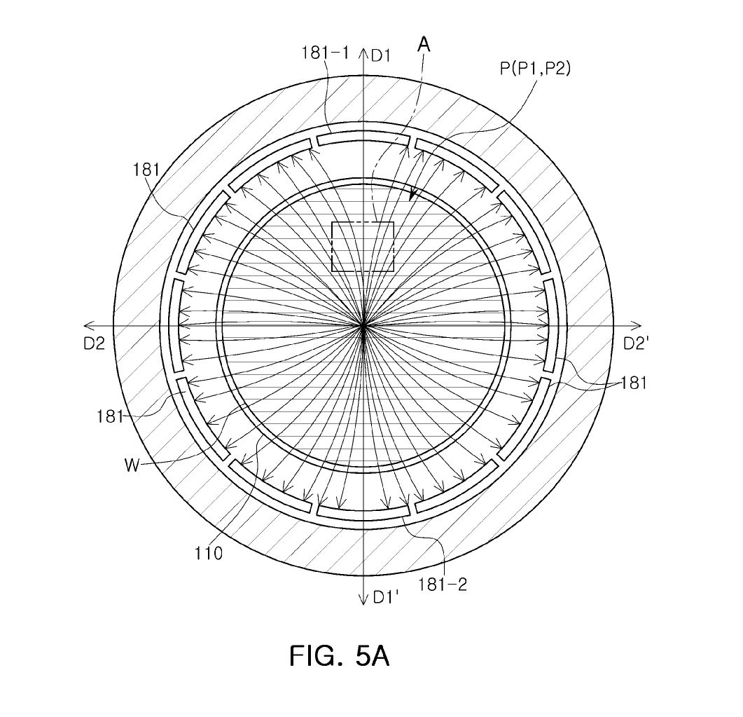

As illustrated in FIG. 4, the gas outlet 181 may be arranged in a circular manner, e.g., may have sections spaced from one another along an outer circumference (of a bottom surface) of the processing chamber 101. The vacuum pump 185, controller 189 and valves 187, or a like exhaust system, may be provided to independently drive thee sections of the gas outlet 181, respectively. Discharge of processing gas may be effectively induced in a desired direction (e.g., D2-D2′ as viewed in a plan view of the device) by way of such independent driving control.

In more detail, the exhaust system, and especially the controller 189 of the present example, may strengthen a flow of processing gas in the direction of the second virtual line D2-D2′ (as viewed in a plan view of the device). In other words, when the vacuum pump 185 associated with the gas outlet 181 is operated during a substrate treatment, pumping power acting to discharge the gas through sections 181-1 and 181-2 aligned in the direction of the first virtual line Dl-D1′ as viewed in a plan view of the device is minimized, i.e., is reduced to less than the pumping power acting to discharge the gas through other sections of the gas outlet 181. Alternatively, the vacuum pump 185 may be shut down.

The flow of the processing gas is dependent on the pressure of the gas when discharged from the showerhead and a gradient of the pumping power produced by the exhaust system. In general, a pressure difference between the gas injecting holes 125 may be relatively great for the sake of producing a uniform discharge. For example, the gas injecting holes 125 disposed at the outer periphery of the discharge surface of the showerhead may be configured to discharge processing gas at a higher pressure than gas injecting holes disposed adjacent to a central portion of the discharge surface. Furthermore, when processing gas is discharged, the velocity of the gas flow may be controlled to be relatively high at an initial stage of the discharge. Thus, even in the case in which the flow of processing gas may be adjusted using the pumping power generated by the exhaust system, the direction of the gas flow (gas flow distribution) in an initial stage of the discharge of the gas from the showerhead is difficult to control by only means of the pumping power.

FIG. 5A illustrates gas flow distribution controlled by only pumping power in a showerhead of the related art, while FIG. 5B illustrates gas flow distribution controlled by the arrangement of gas injecting holes and the pumping power of the exhaust system according to an example of the processing device according to the inventive concept.

FIG. 5A shows gas flow distribution is controlled by only pumping power in the related art because showerheads of the related art have gas injecting holes all inclined in radial directions as viewed in a plan view or substantially perpendicular to the discharge surface. The flow of processing gas along direction D1-D1′ (as viewed in a plan view) may be reduced to a small degree compared to the flow in the other directions, as illustrated by the arrows in FIG. 5A. That is, processing gas may be induced to flow in substantially all radial directions across the interior space of the process chamber.

Therefore, in a case in which a line pattern P on the substrate W is being formed or is oriented in direction D2-D2′, the characteristics of the line pattern P as a result of the process may be faulty. In more detail, in portion “A” of the substrate W illustrated in FIG. 5A, the horizontal component of the processing gas flow is in a direction substantially perpendicular to a direction D2-D2′ in which the line pattern P is being formed or is oriented for further processing. It is difficult to ensure a uniform line pattern as a result of the process in this case, particularly in a case in which processing gas is provided as source gas of a plasma.

In this case, the processing gas is decomposed into ions, active species, or the like, and an energy state of the gas is changed, the plasma having been generated. In the case of active species, as opposed to ions which may be controlled by an electric field, the distribution and flow of active species is mostly determined based on characteristics of a fluid by discharge momentum and pumping control. Therefore, the active species will have the flow distribution described above.

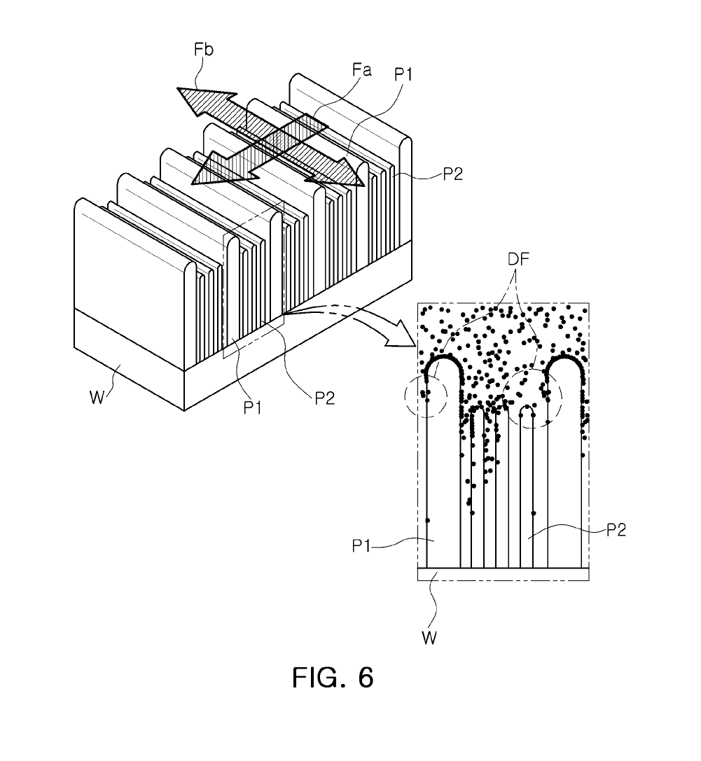

FIG. 6 is an enlarged perspective view of a substrate W in region “A” of FIG. 5A.

With reference to FIG. 6, a semiconductor structure on a substrate W may include a first line pattern P1 and a second line pattern P2, having different heights and widths. For example, the semiconductor structure may be a structure associated with a vertical memory device having a three-dimensionally arrayed memory cell region.

If the processing gas (more specifically, an active species described above) flows in the radial directions, a substantial amount of the active species flows in a direction perpendicular to the line pattern, a shading effect in which a flux of the active species varies across the semiconductor structure may occur.

In other words, as illustrated in FIG. 6, a flow Fa of processing gas is formed in a direction perpendicular to the line patterns P1 and P2. Thus, an area having a relatively low concentration of active species, marked “DF”, may be generated, and an asymmetric reaction may occur on opposing sides of line patterns P1 and P2, thereby significantly degrading process characteristics.

As illustrated in FIGS. 5A and 6, because initial gas flow occurs at a high velocity in a radial direction and pumping power can only alter the gas flow in an outer peripheral region to a small degree, there is a limitation to the extent that gas flow distribution can be controlled in the related art. Certain undesirable gas flow distribution, as was shown in and described above in connection with FIG. 5A, may be a cause of a process defect when a semiconductor device having a line pattern the same as that of a vertical memory device is formed.

In order to form the gas flow in a desired direction (having a horizontal component or as viewed in a plan view in the direction of line D2-D2′) in an example according to the inventive concept, gas injecting holes 125 are provided with a configuration establishing discharge momentum in a desired direction. FIG. 5B illustrates gas flow distribution controlled by virtue of the arrangement of gas injecting holes 125, along with pumping power, in the device illustrated in FIGS. 1 and 2.

With reference to FIG. 5B, gas injecting holes 125L of a first region and gas injecting holes 125R of a second region may be disposed on opposite sides of and inclined in directions perpendicular to first virtual line D1-D1′. Thus, processing gas may flow (as viewed in a plan view) in directions substantially perpendicular to the first virtual line D1-D1′ from the discharge surface 120B of the showerhead 120.

As illustrated in FIG. 5B, the entire flow of processing gas may be parallel with a line pattern (see Fb of FIG. 6). Therefore, active species may be distributed symmetrically on opposing sides of the line pattern. Thus, a uniform reaction may be guaranteed on the opposing sides of the line pattern. Accordingly, a process defect may be prevented, and a sufficient process margin and yield may be secured, particularly in a process of manufacturing a three-dimensional memory device.

Although the above-described benefits and advantages of the inventive concept have been described mostly in connection with a patterning process or an etching process, the same can apply as well to a deposition process. For example, flow of source gas may be formed to be parallel with the longitudinal direction of a line pattern, thereby guaranteeing deposition of a uniform film on the opposing sides of the line pattern.

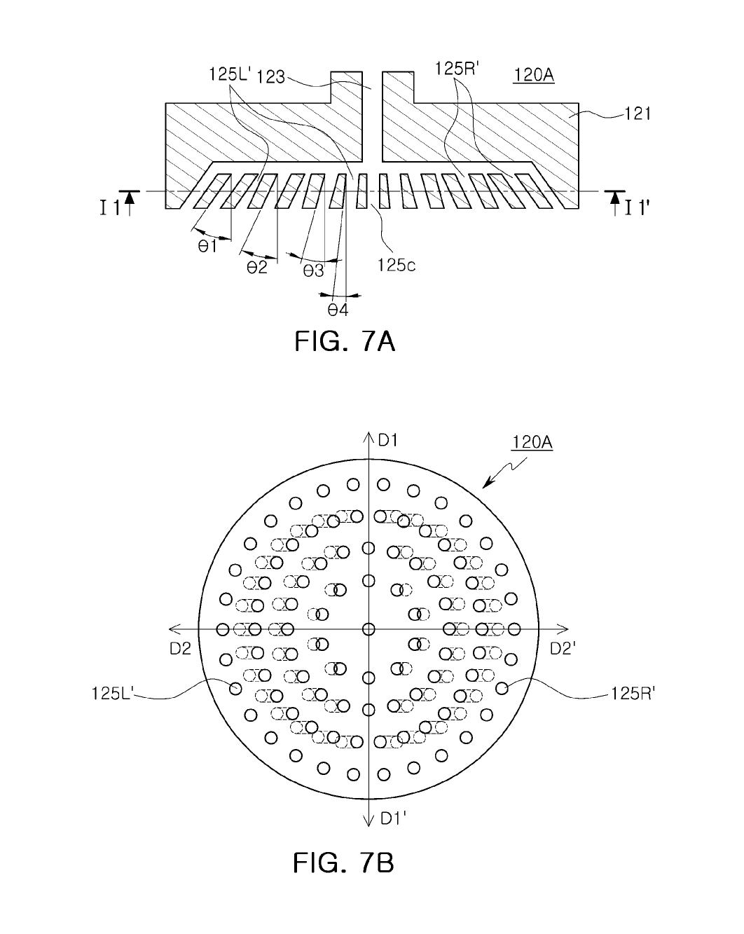

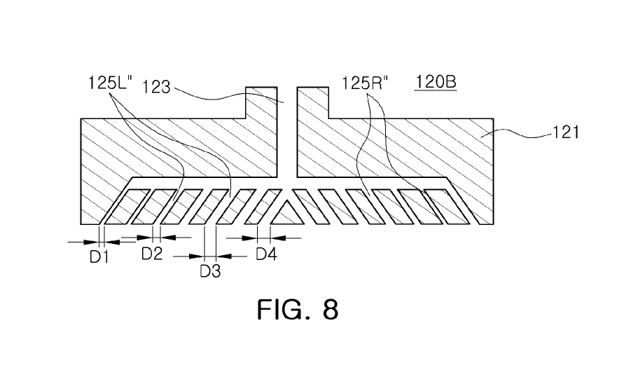

Various examples of a showerhead according to the inventive concept will now be described in detail with reference to FIGS. 7A, 7B, and 8.

With reference to FIGS. 7A and 7B, showerhead 120A is similar to showerhead 120 illustrated in FIG. 2, except that inclination angles θ1, θ2, θ3, and θ4 of the gas injecting holes vary according to distance in the direction of line D2-D2′ from the center of the discharge surface of the showerhead, and in that a set of gas injecting holes 125c are disposed along a center line of the discharge surface (described in more detail below). Therefore, the same descriptions used with reference to the showerhead 120 illustrated in FIG. 2 apply unless otherwise expressly stated to the contrary.

The showerhead 120A has a first region L and a second region R on opposite sides of a first virtual line D1-D1′ passing through a center of a gas discharge surface. Gas injecting holes 125L′ of the first region L and gas injecting holes 125R′ of the second region R may be inclined in opposite directions. The gas injecting holes 125L′ and the gas injecting holes 125R′ may have bilaterally symmetry about the first virtual line D1-D1′.

In an example, the gas injecting holes 125L′ and 125R′ in each region may have inclination angles (θ1>θ2>θ3>θ4) that increase in a direction from the center towards an outer periphery of the gas discharge surface. The greater the inclination angle of the gas injecting hole, the greater is the horizontal component of the momentum of gas flow in the desired direction D2-D2′. In the example described above, the processing gas may flow at a greater inclination angle at an outer peripheral region of the showerhead than at a central region thereof. The inclination angles may vary within a range of about 30° to about 45°.

In addition, a showerhead according to the inventive concept may include gas injecting holes 125c disposed along the first virtual line D1-D1′. The gas injecting holes 125L′ and 125R′ may be formed in a direction substantially perpendicular to the gas discharge surface. The gas injecting holes 125L′ and 125R′ of the first region and the second region may form gas flows in opposite directions, thereby complementing insufficient gas flow in a region disposed adjacent to the first virtual line D1-D1′.

In an example, the gas injecting holes 125L′ and 125R′ in respective regions may have inclination angles (θ1>θ2>θ3>θ4) increased in the direction of the outer periphery thereof and may have an inclination angle equal to those of gas injecting holes disposed adjacent thereto. On the contrary, the gas injecting holes 125L′ and 125R′ may be configured to be inclined to the same degree or less in a direction of the first virtual line D1-D1′.

With reference to FIG. 8, the showerhead 120B according to this example is similar to the showerhead 120 illustrated in FIG. 2, except that diameters D1, D2, D3, and D4 of the gas injecting holes 125L″ and 125R″ vary amongst each other. Therefore, the same descriptions used with reference to the showerhead 120 illustrated in FIG. 2 apply unless otherwise expressly stated to the contrary.

The gas injecting holes 125L″ and 125R″ of the showerhead 120B have diameters (D1<D2<D3<D4) that decrease in a direction from the center to the outer periphery of the gas discharge surface. The smaller the diameter, the greater is the horizontal component of momentum of gas flow in direction D2-D2′. Also, the features described in connection with the example of FIGS. 7A and 7B may be incorporated into this example so that the inclination angles of the gas injecting holes also vary (increase) in a direction from the center to the outer periphery of the gas discharge surface.

In this example, as shown in the figure, respective ones of the gas injecting holes 125L″ and 125R″ may have diameters equal to those of gas injecting holes 125L″ and 125R″ disposed adjacent thereto.

Also, the gas injecting holes are illustrated as being spaced from one another at equal intervals, but the inventive concept is not limited thereto. Intervals between the adjacent gas injecting holes in a given direction may be different. For example, the intervals between the gas injecting holes may decrease in a direction from the center to the outer periphery of the gas discharge surface of the showerhead.

As described above, according to an aspect of the present inventive concept, sets of gas injecting holes of a shower head may be respectively provided in two regions on opposite sides of a center line of a gas discharge surface of the showerhead, and the gas injecting holes of the sets may be respectively inclined in left and right directions substantially perpendicular to the center line, whereby a uniform process can be carried out over an entire region of a specific pattern on a substrate. For example, in a case in which a line pattern is formed on a wafer or a deposition process or an etching process is performed on a wafer having a line pattern, the wafer may be oriented such that the lengthwise dimension of the line pattern is disposed substantially in the direction perpendicular to the virtual center line, whereby a deposition or etching process (e.g., a plasma etching process) may be performed uniformly across the region of the line pattern.

Although examples of the inventive concept have been shown and described above, it will be apparent to those skilled in the art that modifications and variations could be made to such examples without departing from the scope of the present inventive concept as defined by the appended claims.

What is claimed is:

1. A showerhead, comprising:
a body having a first surface, a second surface opposite the first surface, a gas supply channel open at the first surface, and a plurality of gas injecting holes in open communication with the gas supply channel and open at the second surface to allow gas, delivered through the gas supply channel, to be discharged from the showerhead at the second surface,
wherein the second surface has a first region and a second region on opposite sides of a first virtual line passing through a center of the second surface, and
wherein in a vertical sectional view of the body in which the first surface faces up and the second surface faces down, each of the gas injecting holes is inclined, relative to a line perpendicular to the second surface, in a direction whose horizontal component is substantially parallel to the second surface and perpendicular to the first virtual line, and
the gas injecting holes open at the first region of the second surface are inclined oppositely with respect to the gas injecting holes open at the second region in such that gas discharged from the gas injecting holes at the second surface flows away from the first virtual line when viewed in a plan view of the showerhead.

2. The showerhead of claim 1, wherein a respective group of the gas injecting holes is open to the second surface at each of a plurality of concentric regions of the second surface.

3. The showerhead of claim 1, wherein the gas injecting holes are inclined at substantially the same angles as one another.

4. The showerhead of claim 1, wherein the angles at which the gas injecting holes are inclined stay the same as one another or increase as a distance increases from the first virtual line in a direction perpendicular to the first virtual line.

5. The showerhead of claim 1, wherein diameters of the gas injecting holes are equal or decrease as a distance increases from the first virtual line in a direction perpendicular to the first virtual line.

6. The showerhead of claim 1, wherein angles at which the gas injecting holes are inclined are each within a range of 30° to 45°, relative to the line perpendicular to the second surface.

7. The showerhead of claim 1, wherein the plurality of gas injecting holes include a group of gas injecting holes open to the second surface along the first virtual line and extending in a direction substantially perpendicular to the second surface.

8. The showerhead of claim 1, wherein the second surface is substantially circular, the first virtual line passes through the center of the second surface, a respective group of the gas injecting holes is open to the second surface at each of a plurality of concentric circles whose centers coincide with that of the second surface, and the gas injecting holes open at the first region of the second surface have bilateral symmetry with the gas injecting holes open at the second region of the second surface with respect to a plane perpendicular to the second surface and coincident with the first virtual line.

9. The showerhead of claim 8, wherein angles at which the gas injecting holes are inclined are each within a range of 30° to 45°, relative to the line perpendicular to the second surface.

10. A substrate processing device, comprising:
a processing chamber having a reaction space therein;
a substrate support disposed in a lower portion of the processing chamber and dedicated to support a substrate; and
a showerhead disposed in an upper portion of the processing chamber and having a gas discharge surface opposing the substrate support,
wherein the showerhead comprises a body including a gas supply channel and a plurality of gas injecting holes in open communication with the gas supply channel and open at the gas discharge surface such that source gas delivered through the gas supply channel is discharged from the showerhead at the gas discharge surface thereof into the reaction space, the gas discharge surface having a first region and a second region on opposites sides of a first virtual line passing through a center of the gas discharge surface, and
wherein each of the gas injecting holes is inclined, relative to a line perpendicular to the gas discharge surface, in a direction whose horizontal component is substantially parallel to the gas discharge surface and perpendicular to the first virtual line, and
wherein the gas injecting holes open at the first region of the gas discharge surface are inclined oppositely with respect the gas injecting holes open at the second region such that the source gas discharged from the gas injecting holes at the gas discharge surface flows away from the first virtual line when viewed in a plan view of the substrate processing device.

11. The substrate processing device of claim 10, further comprising a radio frequency (RF) power source operatively connected to the showerhead to provide an RF signal to the showerhead.

12. The substrate processing device of claim 10, wherein the processing chamber has a gas outlet disposed at a level lower than a level of a substrate support surface of the substrate, and the gas outlet has a plurality of sections disposed in a circumferential direction of a lower part of the processing chamber.

13. The substrate processing device of claim 12, wherein the sections of the gas outlet include first sections across from one another in the direction of the first virtual line, and second sections interposed, in said circumferential direction of the lower part of the processing chamber, between the first sections,
further comprising an exhaust system including a pump connected to the gas outlet to pump gas out of the process chamber through the gas outlet, and control means for independently controlling a pumping of the gas through the sections of the gas outlet or controlling an operation of the pump.

14. The substrate processing device of claim 10, wherein a respective group of the gas injecting holes is open to the gas discharge surface at each of a plurality of concentric regions of the gas discharge, and
the gas injecting holes open at the first region of the gas discharge surface have bilateral symmetry with the gas injecting holes open at the second region of the gas discharge surface with respect to a plane perpendicular to the gas discharge surface and coincident with the first virtual line.

15. The substrate processing device of claim 10, wherein angles at which the gas injecting holes are inclined are each within a range of 30° to 45°, relative to the line perpendicular to the gas discharge surface, and are substantially equal to one another.

16. The substrate processing device of claim 10, wherein angles at which the gas injecting holes are inclined are each within a range of 30° to 45°, relative to the line perpendicular to the gas discharge surface, and
the angles at which the gas injecting holes are inclined stay the same as one another or increase as a distance increases from the first virtual line in a direction perpendicular to the first virtual line.

17. The substrate processing device of claim 10, wherein diameters of the gas injecting holes are equal or decrease as a distance increases from the first virtual line in a direction perpendicular to the first virtual line

18. The substrate processing device of claim 10, wherein the plurality of gas injecting holes include a group of gas injecting holes open to the gas discharge surface along the first virtual line and extending in a direction substantially perpendicular to the gas discharge surface.

19. A substrate processing device, comprising:
a processing chamber having a reaction space therein, and lower part including a gas outlet;
a substrate support disposed in a lower portion of the processing chamber and dedicated to support a substrate, the substrate support having a substrate support surface disposed at a level above that of the gas outlet;
a showerhead disposed in an upper portion of the processing chamber and having a gas discharge surface opposing the substrate support; and
an exhaust system connected to the gas outlet to draw gas out of the process chamber through the gas outlet,
wherein the showerhead comprises a body including a gas supply channel and a plurality of gas injecting holes in open communication with the gas supply channel and open at the gas discharge surface such that source gas delivered through the gas supply channel is discharged from the showerhead at the gas discharge surface thereof into the reaction space, the gas discharge surface having a first region and a second region on opposites sides of a first virtual line passing through a center of the gas discharge surface, and
wherein each of the gas injecting holes is inclined, relative to a line perpendicular to the gas discharge surface, in a direction whose horizontal component is substantially parallel to the gas discharge surface and perpendicular to the first virtual line,
wherein the gas injecting holes open at the first region of the gas discharge surface are inclined oppositely with respect to the gas injecting holes open at the second region such that the source gas discharged from the gas injecting holes at the gas discharge surface flows away from the first virtual line when viewed in a plan view of the substrate processing device, and
wherein the gas outlet has a plurality of sections disposed as spaced from each other in a circumferential direction of the lower part of the processing chamber.

20. The substrate processing device of claim 19, wherein the exhaust system includes a pump connected to the sections of the gas outlet, valves disposed in line between the sections of the gas outlet, respectively, and the pump, and a controller operatively connected to the valves and/or to the pump.
